(19) United States
(12) Patent Application Publication
(10) Pub. No.: US 2006/0028265 A1
(43) Pub. Date: Feb. 9, 2006

(54) Device for generating a gamma correction voltage and display ultilizing the same

(76) Inventor: Yung-Yu Tsai, Tainan County (TW)

Correspondence Address: RABIN & Berdo, PC, 1101 14TH STREET, NW, SUITE 500, WASHINGTON, DC, 20005, US

(21) Appl. No.: 11/197,492

(22) Filed: Aug. 5, 2005

(30) Foreign Application Priority Data
Aug. 9, 2004 (TW) 93123775

(51) Int. Cl. G11C 5/14

(52) U.S. Cl. 327/530

(57) ABSTRACT

A device for generating a Gamma correction voltage in a display is disclosed. The device comprises an integrated-circuit device and a Gamma correction voltage generating circuit. In the invention, a part of the Gamma correction generating circuit is disposed inside the integrated-circuit device. Compared to a conventional Gamma correction voltage generating circuit disposed outside an integrated-circuit device, the device of the invention employs less electronic elements, thereby reducing circuit cost.

This application claims the benefit of Taiwan application Serial No. 93123775, filed Aug. 9, 2004, the subject matter of which is incorporated herein by reference.

### BACKGROUND OF THE INVENTION

1. Field of the Invention

The invention relates in general to a device for generating a Gamma correction voltage, and more particularly to a device for generating a Gamma correction voltage disposed inside a driving integrated-circuit device of a display.

2. Description of the Related Art

Due to nonlinear relation between monitor gray values and signal voltages or between monitor gray values and monitor brightness in a display, Gamma parameter correction should be made (by inputting a Gamma correction voltage) for the display to obtain a linear relation between the above-mentioned parameters and thus to display high-quality pictures.

In a conventional liquid crystal display, Gamma correction voltages are generated by a Gamma correction voltage generating circuit as shown in FIG. 1. The Gamma correction voltage generating circuit 10 generates and outputs Gamma correction voltages G1˜Gn to a driving integrated-circuit device (or a driving IC) 1000 so that the driving IC 1000 can generate and output correct Gamma voltages to a display panel to display pictures of correct brightness.

The Gamma correction voltage generating circuit 10 can be composed of a resist series 100 as shown in FIG. 2, which has one end connected to a reference voltage and the other end grounded. By connecting the Gamma correction voltage generating circuit 10 to a resist series 20 in the driving IC 1000, the Gamma correction voltages G1˜Gn can be output to the driving IC 1000 to generate correct Gamma voltages.

Due to resist deviation of the resist series 20 of the driving IC 1000 occurred in manufacturing process, a number of parallel-connected operational amplifiers 120 have to be configured between the resist series 100 and 20 so as to prevent the resist deviation issue, as shown in FIG. 3.

However, the resist series 100 has a constant voltage output and has a less flexibility in design, which cannot satisfy different requirements for Gamma correction voltages. Moreover, this type of Gamma correction voltage generating circuit cannot also cope with the requirement of dynamic Gamma correction voltages, and devices for generating Gamma correction voltages are all disposed on a circuit board outside the driving IC, thereby increasing circuit cost.

Another conventional method for generating Gamma correction voltages is shown in FIG. 4. By using a timing controller (TCON) 40 to drive a programmable digital to analog converter (DAC) 50, Gamma correction voltages G1˜Gn are generated and outputted to the driving IC 1000 to generate correct Gamma voltages. However, the devices for generating Gamma correction voltages are still disposed on the circuit board outside the driving IC, thereby increasing circuit cost.

### SUMMARY OF THE INVENTION

It is therefore an object of the invention to provide a device for generating a Gamma correction voltage, whose components are disposed inside a driving IC, so as to reduce its circuit cost and increase its design flexibility.

The invention achieves the above-identified object by providing a device for generating a Gamma correction voltage including an integrated-circuit device and a Gamma correction voltage generating circuit. The Gamma correction voltage generating circuit includes a first circuit, disposed inside the integrated-circuit device, and a second circuit, disposed outside the integrated-circuit device. The first circuit has at least an input terminal for receiving a signal from the second circuit, and at least an output terminal for outputting a Gamma correction voltage.

The device for generating a Gamma correction voltage of the invention further includes a voltage source, disposed outside the integrated-circuit device and connected to the second circuit. The voltage source inputs a voltage signal to the first circuit via the input terminal and outputs the Gamma correction voltage via the output terminal.

The first circuit includes an operational amplifier, and the voltage source inputs the voltage signal to the operational amplifier via the input terminal and outputs the Gamma correction voltage via the output terminal.

The device for generating a Gamma correction voltage further includes a bus connected to the input terminal for inputting a control signal to the first circuit and outputting the Gamma correction voltage via the output terminal. The first circuit can be a digital to analog converter or a pulse width modulation (PWM) circuit.

In the device for generating a Gamma correction voltage of the invention, the bus includes a clock input line for inputting a clock signal and a data input line for inputting a data signal and a control signal.

In the device for generating a Gamma correction voltage of the invention, the bust includes a clock input line for inputting a clock signal, a data input line for inputting a data signal, and a control signal input line for inputting a control signal.

The invention achieves the above-identified object by providing a display including a display panel, a number of integrated-circuit devices for driving the display panel, and a number of Gamma correction voltage generating circuits. Each Gamma correction voltage generating circuit includes a first circuit, disposed inside the corresponding integrated-circuit device for generating a Gamma correction voltage and a second circuit, disposed outside the corresponding integrated-circuit device. Each of the first circuits has at least an input terminal for receiving a signal from the second circuit, and at least an output terminal for outputting a Gamma correction voltage.

In the display of the invention, each integrated-circuit device has a number of input terminals for receiving the Gamma correction voltages from other integrated-circuit devices.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a block diagram of a conventional Gamma correction voltage generating circuit.

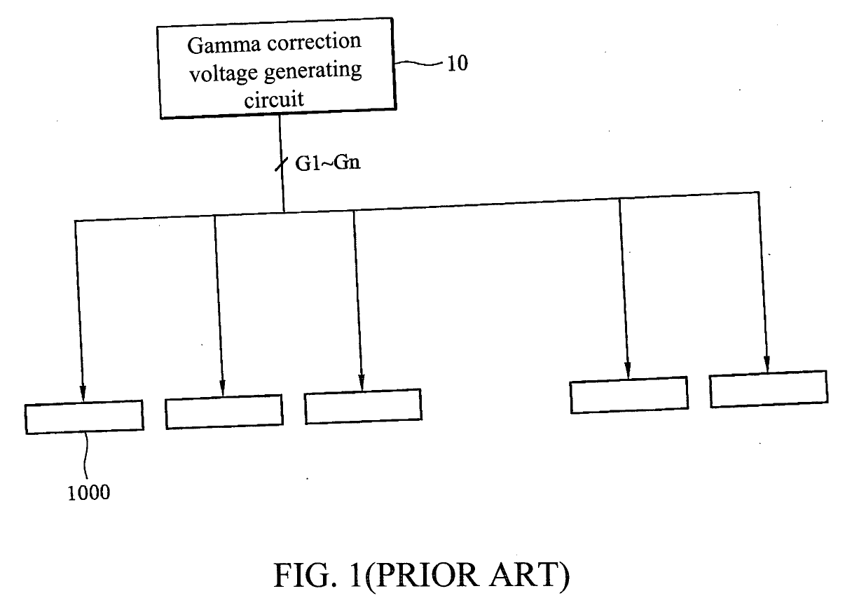

FIG. 2 (Prior Art) illustrates one conventional Gamma correction voltage generating circuit.

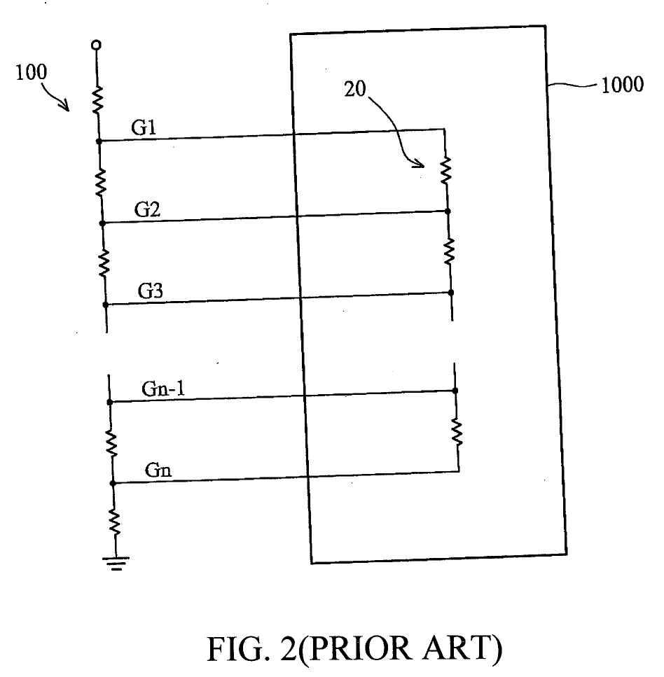

FIG. 3 (Prior Art) illustrates another conventional Gamma correction voltage generating circuit.

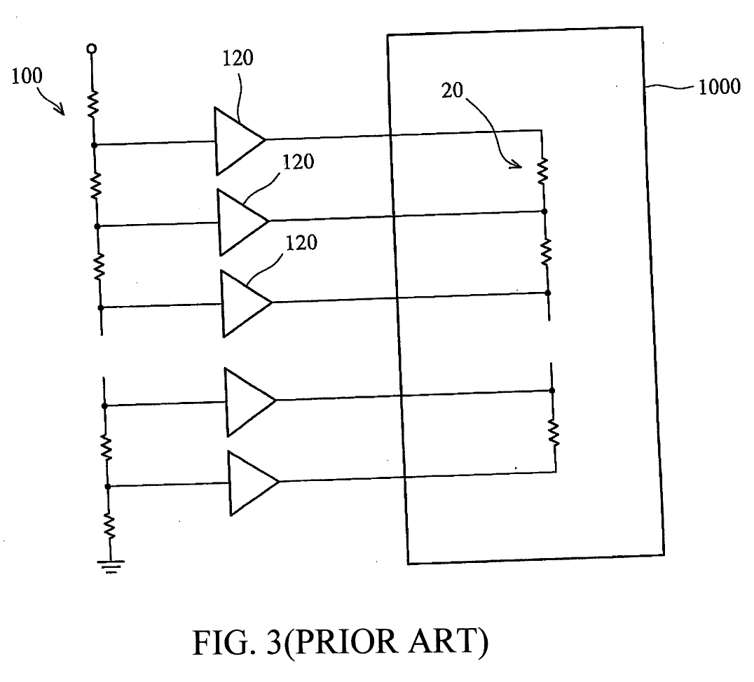

FIG. 4 (Prior Art) shows the block diagram of another conventional Gamma correction voltage generating circuit.

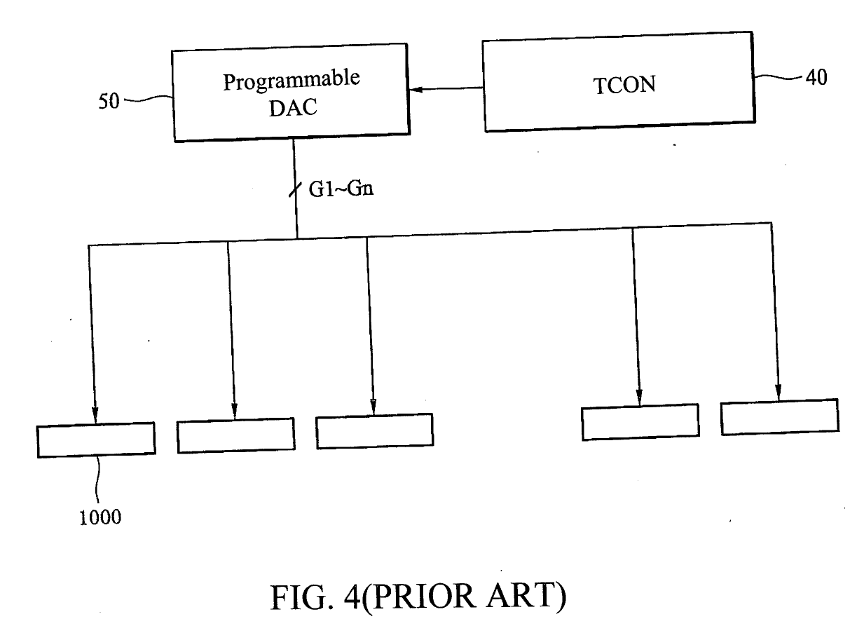

FIG. 5 shows a block diagram of a Gamma correction voltage generating circuit according to the first embodiment of the invention.

FIG. 6 illustrates a Gamma correction voltage generating circuit according to the first embodiment of the invention.

FIG. 7 illustrates the distribution of the Gamma correction voltages according to the preferred embodiment of the invention.

FIG. 8 shows a block diagram of a Gamma correction voltage generating circuit according to the second embodiment of the invention.

FIG. 9 illustrates a Gamma correction voltage generating circuit according to the second embodiment of the invention.

FIG. 10 illustrates another Gamma correction voltage generating circuit according to the second embodiment of the invention.

### DETAILED DESCRIPTION OF THE INVENTION

### Embodiment One

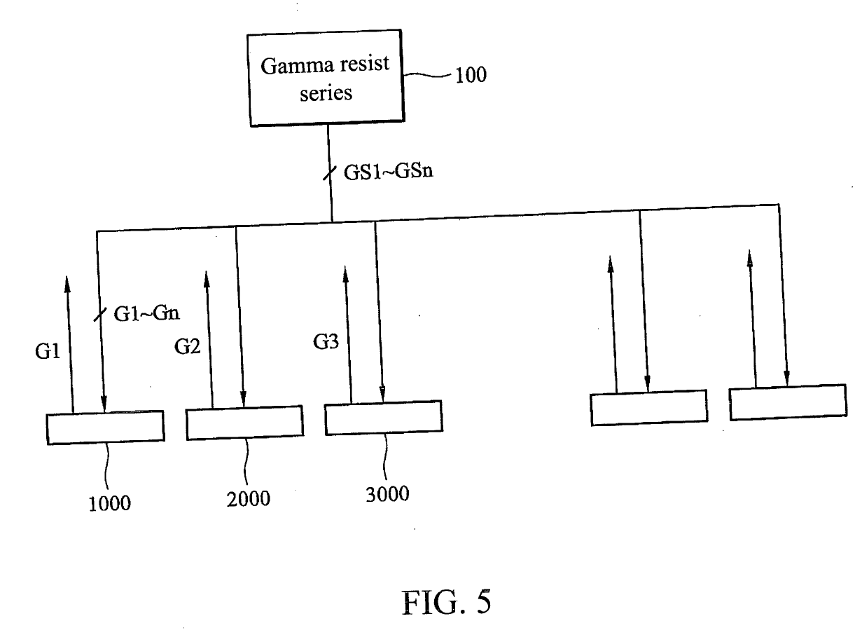

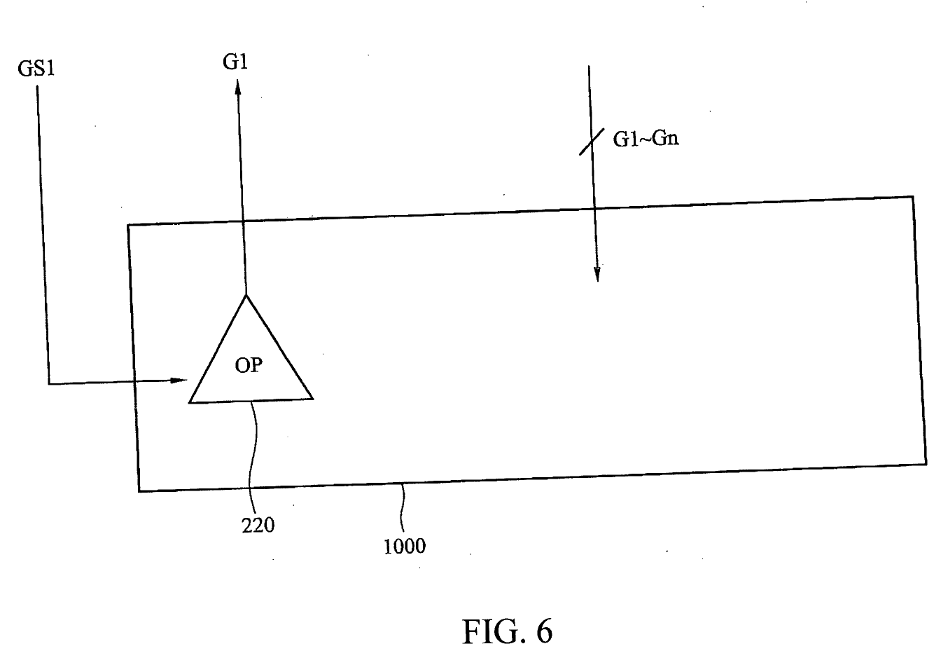

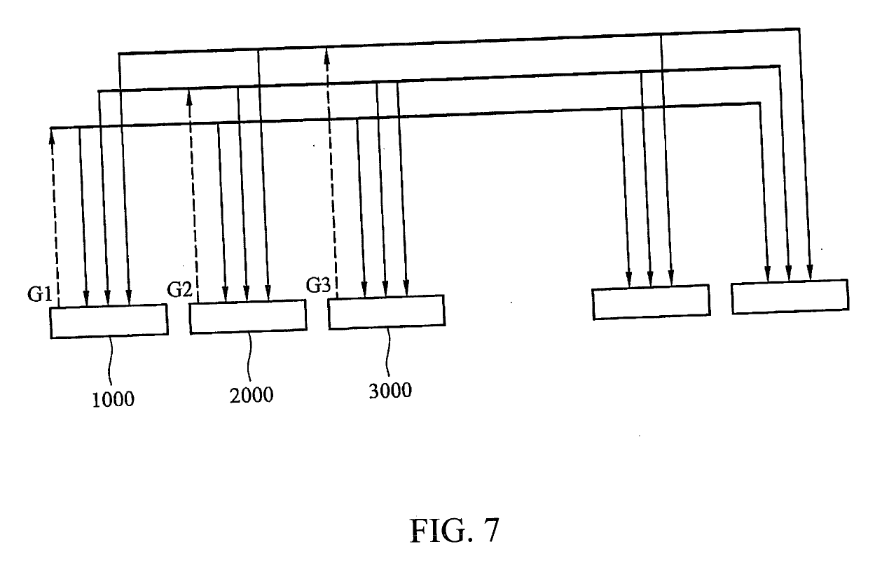

The first embodiment of the invention is shown in FIG. 5 and FIG. 6. The resist series 100 is remained outside the driving IC 1000, but operational amplifiers 220 are respectively disposed in driving ICs 1000, 2000, 3000, . . . . As shown in FIG. 6, Gamma source voltages GS1˜GSn are output via the resist series 100 to the operational amplifiers 220, and Gamma correction voltages G1˜Gn generated by the operational amplifiers 220 are output via the driving IC 1000 and then distributed to other driving ICs 2000, 3000, . . . by the method shown in FIG. 7. For example, the correction voltage G1 output by the driving IC 1000 is distributed to other driving ICs 2000, 3000, . . . while the correction voltage G2 output by the driving IC 2000 is distributed to other driving ICs 1000, 3000, . . . , and so on. Each driving IC outputs a correction voltage to other driving ICs and each driving IC as receiving correction voltages from other driving ICs can output a correct Gamma voltage to a liquid crystal panel.

### Embodiment Two

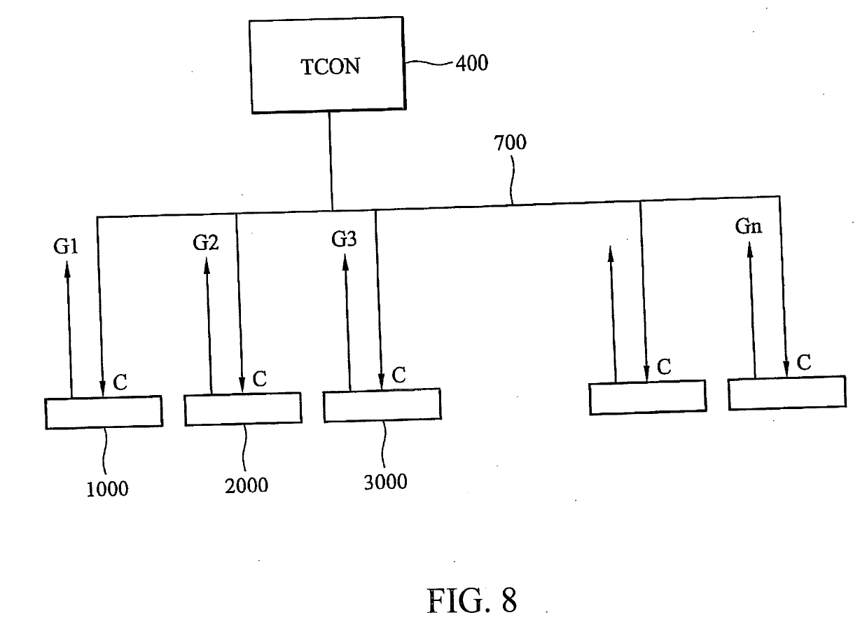

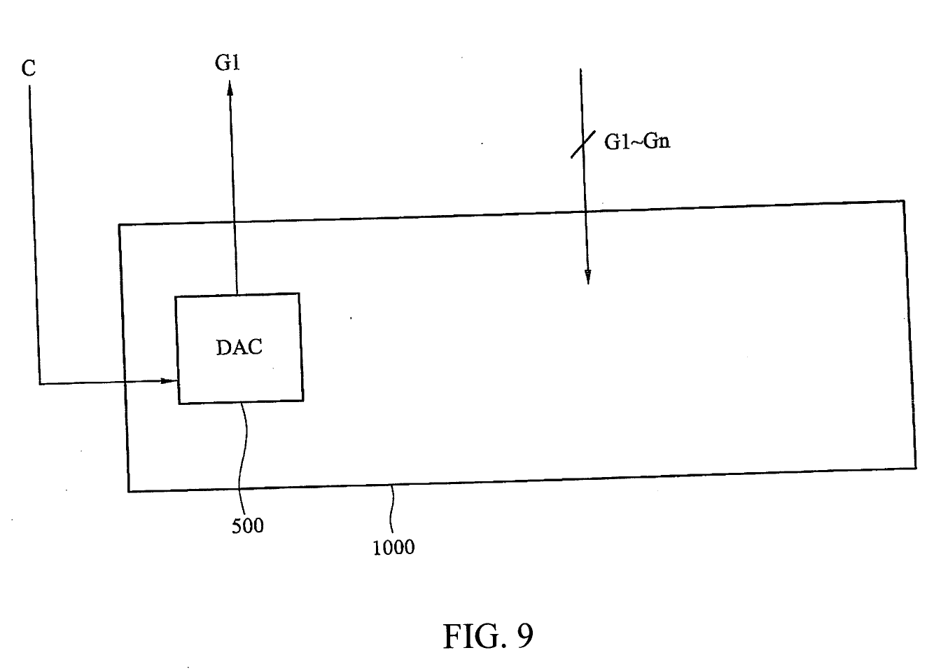

The second embodiment of the invention is shown in FIG. 8 and FIG. 9. A DAC 500 for generating Gamma correction voltages is disposed in the driving IC 1000, and a TCON 400 inputs a digital control signal C from the exterior of the driving IC 1000 to the DAC 500 via a bus 700 to generate Gamma correction voltages. The Gamma correction voltages are respectively distributed in average to other driving ICs 2000, 3000, . . . by the method as shown in FIG. 7.

### Embodiment Three

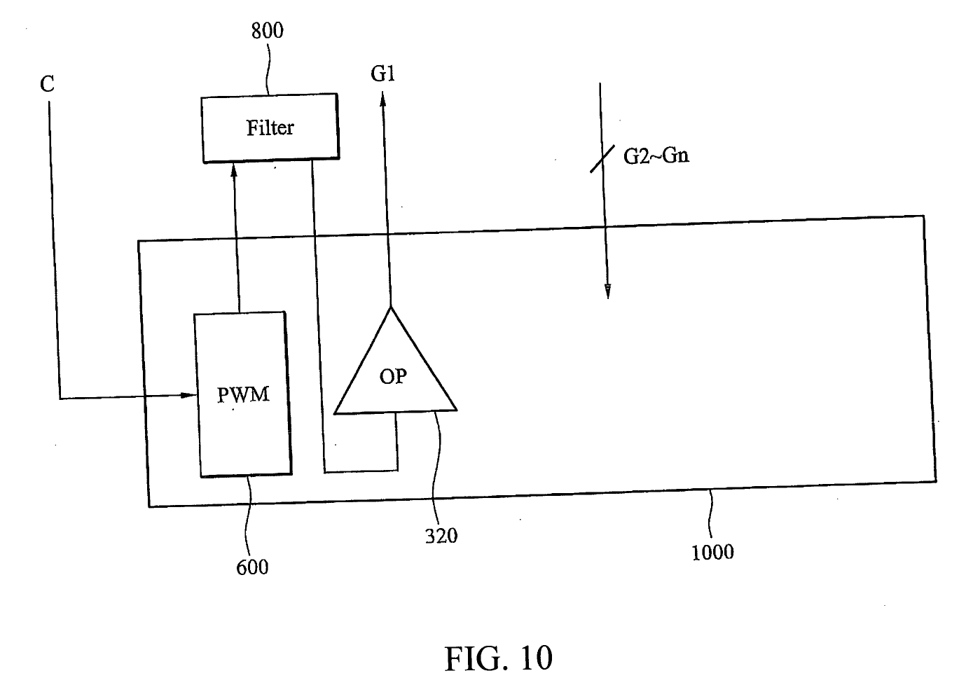

In addition to using the DAC 500, a pulse width modulation (PWM) circuit 600 can also be disposed in the driving IC 1000 by the method as shown in FIG. 10. The TCON 400 inputs a digital control signal C from the exterior of the driving IC 1000 to the PWM circuit 600 and the signal output from the PWM circuit 600 is transferred by a filter circuit 800 and an operational amplifier 320 to be a Gamma correction voltage G1. The Gamma correction voltage G1 is further distributed to other driving ICs 2000, 3000, . . . by the method shown in FIG. 7.

In the embodiment, the above-mentioned bus 700 can use a share data bus to input the control signal to the driving IC via a signal transmission line for inputting data signals. In this structure, the bus includes a clock input line for inputting a clock signal, and a data input line for simultaneously inputting a data signal and a control signal.

The bus 700 mentioned above can also has an independent control signal line for inputting the control signal to the driving IC. In this structure, the bus includes a clock input line for inputting a clock signal, a data input line for inputting a data signal, and a control signal input line for inputting the control signal C.

Invention Performance

In the invention, the device for generating a Gamma correction voltage is disposed inside the driving IC to lower the amount of devices disposed in exterior circuit. Therefore, the circuit cost can be reduced and the flexibility in circuit design can also be increased.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A device for generating a Gamma correction voltage, comprising:
at least an integrated-circuit device; and
a Gamma correction voltage generating circuit, comprising a first circuit, disposed inside the integrated-circuit device, and a second circuit, disposed outside the integrated-circuit device, the first circuit having at least an input terminal for receiving a signal from the second circuit, and at least an output terminal for outputting a Gamma correction voltage to all the integrated-circuit devices.

2. The device for generating a Gamma correction voltage according to claim 1, further comprising a voltage source, disposed outside the integrated-circuit device and connected to the second circuit, wherein the voltage source inputs a voltage signal to the first circuit via the input terminal and outputs the Gamma correction voltage via the output terminal.

3. The device for generating a Gamma correction voltage according to claim 2, wherein the first circuit comprises an operational amplifier, the voltage source inputs the voltage signal to the operational amplifier via the input terminal and outputs the Gamma correction voltage via the output terminal.

4. The device for generating a Gamma correction voltage according to claim 1, further comprising a bus, connected to the input terminal, for inputting a control signal to the first circuit and outputting the Gamma correction voltage via the output terminal.

5. The device for generating a Gamma correction voltage according to claim 1, wherein the second circuit comprises a timing controller.

6. The device for generating a Gamma correction voltage according to claim 4, wherein the first circuit comprising a digital to analog converter.

7. The device for generating a Gamma correction voltage according to claim 4, wherein the first circuit comprises a pulse width modulation (PWM) circuit.

8. The device for generating a Gamma correction voltage according to claim 4, wherein the first circuit comprises a filter circuit.

9. The device for generating a Gamma correction voltage according to claim 4, wherein the bus comprises a clock input line for inputting a clock signal and a data input line for inputting a data signal and the control signal.

10. The device for generating a Gamma correction voltage according to claim 4, wherein the bust comprises a clock input line for inputting a clock signal, a data input line for inputting a data signal, and a control signal input line for inputting the control signal.

11. A display, comprising:
A display panel;
A plurality of integrated-circuit devices, for driving the display panel; and
A plurality of Gamma correction voltage generating circuits, each comprising a first circuit, disposed inside the corresponding integrated-circuit device for generating a Gamma correction voltage and a second circuit, disposed outside the corresponding integrated-circuit device, each of the first circuits having at least an input terminal for receiving a signal from the second circuit, and at least an output terminal for outputting a Gamma correction voltage.

12. The display according to claim 11, wherein each of the integrated-circuit device has a plurality of input terminals for receiving the Gamma correction voltage from other integrated-circuit devices.
